(19) United States
(12) Patent Application Publication
(10) Pub. No.: US 2007/0266945 A1
(43) Pub. Date: Nov. 22, 2007

(54) PLASMA CVD APPARATUS EQUIPPED WITH PLASMA BLOCKING INSULATION PLATE

(75) Inventors: Mitsutoshi Shuto, Tama (JP); Yasushi Fukasawa, Tama (JP); Ryu Nakano, Tokyo (JP); Yasuaki Suzuki, Tama (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 11/748,263

(22) Filed: May 14, 2007

Related U.S. Application Data
(60) Provisional application No. 60/800,670, filed on May 16, 2006.

(51) Int. Cl. H05H 1/24; C23C 16/00

(52) U.S. Cl. 118/723 E; 427/569

(57) ABSTRACT

A plasma CVD apparatus for forming a thin film on a substrate includes: a vacuum chamber; an upper electrode; a susceptor as a lower electrode; and a ring-shaped insulation plate disposed in a gap between the susceptor and an inner wall of the chamber in the vicinity of or in contact with the susceptor to minimize a floating potential charged on the substrate while processing the substrate.

### CROSS-REFERENCE TO RELATED APPLICATIONS

This application claims the benefit of U.S. Provisional Application No. 60/800,670, filed May 16, 2006, the disclosure of which is herein incorporated by reference in its entirety.

### BACKGROUND OF THE INVENTION

1. Field of the Invention

The present invention generally relates to a plasma CVD apparatus, particularly to a single-wafer processing plasma CVD apparatus.

2. Description of the Related Art

On manufacturing lines using semiconductor apparatuses, dry etching, plasma CVD and other plasma processes are widely used. The plasma CVD apparatus shown in FIG. 1 is one example of the apparatus used to implement these plasma processes. This plasma CVD apparatus for forming a film on a semiconductor substrate 11 comprises a reactor chamber 1, a susceptor 15 (with a top plate 9 and a heating block 10) located in the reactor chamber 1 and used to place the semiconductor substrate 11 on top, a showerhead 7 facing the susceptor and connected to a gas introduction pipe 6 used to inject reaction gas uniformly onto the semiconductor substrate, an exhaust port 4 for exhausting the interior of the reactor chamber and an exhaust piping 5 connected to the exhaust port, an opening 2 and a gate valve 3 for transferring the semiconductor substrate 11 into and out of the reactor chamber, and a high-frequency power supply 8 located outside the reactor chamber and used to apply a specified voltage to the showerhead.

The showerhead 7 and susceptor 15 also serve as electrodes, and their surfaces are covered with an anodized film.

Other parts such as the interior walls of the reactor chamber are not covered with any insulation material and aluminum and other conductive substances are exposed.

A floating potential generates in the semiconductor substrate due to electrons produced during the plasma processing, where a high floating potential may cause charging damage or pickup problem.

### SUMMARY OF THE INVENTION

To address the aforementioned problems, the plasma processing conditions can be adjusted to reduce the floating potential. However, in many cases adjusting the plasma processing conditions is not sufficiently effective, and reducing the floating potential using this method also presents a number of problems such as the film quality and other requirements not being satisfied. For this reason, it is necessary to change the apparatus structure to reduce the floating potential applied to the semiconductor substrate.

In conventional apparatuses, conductive materials constituting the interior walls of the reactor, etc., are exposed and also plasma is not insulated from the grounding part. These are factors that are likely to increase the floating potential applied to the semiconductor substrate.

Methods that help address the floating potential problem are known, such as producing the entire reactor using ceramics or other insulation materials or covering the interior of the reactor with an insulator (such as U.S. Pat. No. 5,336,585 and Japanese Patent Laid-open No. Hei 6-298596). However, these technologies are not intended to reduce the floating potential, but they have other objects such as preventing contamination. Also, covering the interior walls of the reactor with an insulation material requires major changes to the apparatus structure and this method is not applicable to current apparatuses. For these reasons, different measures that can be easily applied to current apparatuses are needed.

To solve at least one of the problems mentioned above, an embodiment of the present invention has an insulation plate set around the susceptor.

This way, the area in which plasma generates can be limited. Through various other embodiments, the present invention also prevents plasma from coming in contact with the side faces of the heating block, interior walls of the reactor and other locations where conductive members are exposed, which consequently results in a lower floating potential applied to the processing target. As a result, occurrences of charging damage caused by plasma and pickup problem can be reduced.

For purposes of summarizing the invention and the advantages achieved over the related art, certain objects and advantages of the invention have been described above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and not to scale.

FIG. 1 is a schematic diagram of a conventional plasma CVD apparatus.

FIG. 2 is a schematic diagram of a plasma CVD apparatus according to an embodiment of the present invention, wherein a plasma blocking insulation plate is placed on a top plate having an annular step to which the insulation plate is fitted.

FIG. 3 is a schematic diagram of a plasma CVD apparatus according to an embodiment of the present invention, wherein a plasma blocking insulation plate is placed on a top plate having no lip portion, and the insulation plate serves as a lip portion.

FIG. 4 is a schematic diagram of a plasma CVD apparatus according to an embodiment of the present invention, wherein a plasma blocking insulation plate is placed between a top plate and a heating block, either of the top plate or the heating block having an annular groove to which the insulation plate is fitted.

FIG. 5 is a schematic diagram of a plasma CVD apparatus according to an embodiment of the present invention, wherein a plasma blocking insulation plate is placed on a side of a heating block.

FIG. 6 is a schematic diagram of a plasma CVD apparatus according to an embodiment of the present invention, wherein a plasma blocking insulation plate is placed on a side of a heating block and has a complex shape.

FIG. 7 is a schematic diagram of a plasma CVD apparatus according to an embodiment of the present invention, wherein a plasma blocking insulation plate is fixed to a bottom of the reactor at a position higher than a heating block.

FIG. 8 is a schematic diagram of a plasma CVD apparatus according to an embodiment of the present invention, wherein multiple plasma blocking insulation plates are disposed.

FIG. 9 is a graph showing changes of floating potential charged on the substrate in a conventional plasma CVD apparatus and in a plasma CVD apparatus according to an embodiment of the present invention.

FIGS. 10(a) and 10(b) are schematic diagrams of a plasma CVD apparatus according to an embodiment of the present invention. FIG. 10(a) is a schematic front view, and FIG. 10(b) is a cross sectional view taken along line B-B.

FIGS. 11(a)-11(c) are schematic diagrams of three types of susceptor usable in embodiments of the present invention.

FIG. 12 is a schematic diagram of a plasma CVD apparatus according to an embodiment of the present invention (modified Eagle®-10, ASM Japan, Tokyo).

FIG. 13 is a schematic diagram of a plasma CVD apparatus wherein the insulation plate is positioned too low.

FIG. 14 is a schematic diagram of a system for measuring a floating potential of the substrate.

### DETAILED DESCRIPTION OF THE PREFERRED EMBODIMENT

The present invention will be explained below with reference to preferred embodiments. However the preferred embodiments are not intended to limit the present invention.

In an embodiment, the present invention provides a plasma CVD apparatus for processing (e.g., forming a thin film) a substrate, comprising: (i) a vacuum chamber having an inner wall; (ii) an upper electrode (e.g., a shower-plate) installed inside the vacuum chamber; (iii) a susceptor serving as a lower electrode provided with a heater and having a substrate-supporting area for placing the substrate thereon, said susceptor facing (e.g., conductively-coupled to) the upper electrode, enclosed by the inner wall with a gap between an outer periphery of the susceptor and the inner wall, and positioned at a processing position for processing the substrate; and (iv) at least one plasma blocking insulation plate disposed in the gap in the vicinity of or in contact with the susceptor and surrounding all around the susceptor when at the processing position, the insulation plate having an upper surface, a lower surface, and an outer periphery, wherein the lower surface of the insulation plate is not higher than a top surface of the susceptor in an axial direction of the susceptor, the upper surface of the insulation plate is not lower than a lower end of the susceptor, the outer periphery of the insulation plate is located closer to the inner wall of the chamber than to the periphery of the susceptor when at the processing position.

According to the above embodiment, despite the fact that the structure is simple, a plasma generated in the chamber can effectively be confined above the substrate, thereby inhibiting contact of a plasma with an exposed conductive part such as a side of the susceptor and an inner wall of the chamber. As a result, a floating potential of the substrate can effectively be minimized, and a change of floating potential can be suppressed when a plasma is generated. Thus, a problem of charging damage and/or a problem of adhesion of the substrate to the susceptor can effectively be alleviated.

In the above, in an embodiment, the gap between the inner wall and the susceptor may be about 4 cm or greater (e.g., 4-10 cm). The gap can vary depending on the type and size of apparatus. For example, a PECVD apparatus for treating a substrate having a diameter of 8 inches may have a gap of about 6 cm, whereas a PECVD apparatus for treating a substrate having a diameter of 12 inches may have a gap of about 5 cm.

An exposed conductive part which can effectively be covered by the insulation plate includes an inner wall of the chamber, a side of the susceptor, a ring duct, etc., which are typically made of aluminum.

A distance A from the outer periphery of the susceptor to the outer periphery of the insulation plate and a distance B from the outer periphery of the insulation plate to the inner wall of the chamber may satisfy the following equation: A/(A+B)=50-99% (including 60%, 70%, 80%, 90%, 95%, and ranges between any two numbers of the foregoing, preferably 70-98%, more preferably 90% or higher). The distance is measured in a direction perpendicular to the axial direction of the susceptor.

The insulation plate may have an inner periphery which has a diameter greater than a diameter of the substrate-supporting area to be placed on the susceptor. When the insulation plate is attached to a top surface of the susceptor, the inner diameter of the insulation plate is greater than the diameter of the substrate-supporting area (or the substrate).

The insulation plate may be ring-shaped and attached to the susceptor or fixed to the chamber. In the former, the susceptor may have an annular lip portion on its top surface outside the substrate-supporting area, and the insulation plate may be disposed on the top surface outside the lip portion. Alternatively, the top plate may have no annular lip portion on a top surface outside the substrate-supporting area, and the insulation plate may be disposed on the top surface outside the substrate-supporting area.

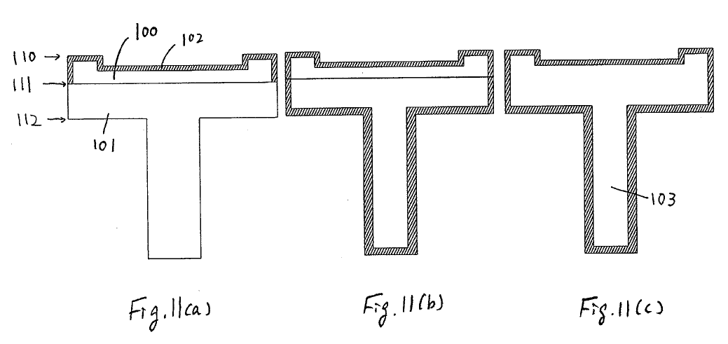

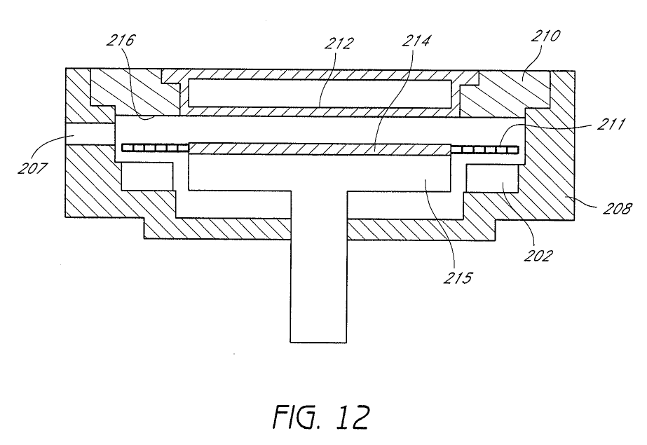

The susceptor can be a single piece in which a heater is embedded, or two pieces (a top plate and a heating block) attached together. The top surface of the top plate may be anode-treated to cover it with an anodic oxide film. FIGS. 11(a) to 11(c) show three types of susceptor. The susceptors shown in FIGS. 11(a) and 11(b) are composed of a top plate 100 and a heating block 101, and the susceptor shown in FIG. 11(c) shows composed of a single piece 103. The heating block of the susceptor shown in FIG. 11(a) has no anodic oxide film and exposes an aluminum surface. Thus, in this case, the insulation plate may be placed above the a boundary 111 between the top plate 100 and the heating block 101. The heating blocks of the susceptors shown in FIGS. 11(b) and 11(c) are coated with an anodic oxide film 102. Thus, the insulation plate may be placed below the boundary 111. However, even if the susceptors shown in FIGS. 11(b) and 11(c) are used, the insulation plate may be placed above a lower end 112 of the heating block 101 or the susceptor, in order to block a plasma from entering under the susceptor (see FIG. 12). The insulation plate may also be placed below the top surface 110 of the susceptor (the lower surface of the insulation plate is lower than the top surface of the susceptor).

The above includes, but is not limited to, the following embodiments: The susceptor is comprised of a top plate and a heating block on which the top plate is placed, wherein the insulation plate is ring-shaped and attached to the top plate. The susceptor is comprised of a top plate and a heating block on which the top plate is placed, wherein the insulation plate is ring-shaped and interposed between the top plate and the heating block. The susceptor is comprised of a top plate and a heating block on which the top plate is placed, wherein the insulation plate is ring-shaped and attached to a side of the heating block. The susceptor is comprised of a top plate and a heating block on which the top plate is placed, wherein the insulation plate has a ring portion and an annular upright peripheral portion, said ring portion being attached to a side of the heating block. The susceptor is comprised of a top plate and a heating block on which the top plate is placed, wherein the insulation plate is ring-shaped, fixed to a bottom of the chamber with a support, and disposed at or near a boundary between the top plate and the heating block when at the processing position.

Further, the at least one insulation plate may be composed of two insulation plates installed in different positions. One of the insulation plates may be attached to a top surface of the susceptor, and the other insulation plate may be fixed to a bottom of the chamber with a support.

The insulation plate may be made of a material selected from the group consisting of oxides, nitrides, and fluorides of aluminum, magnesium, silicon, titanium, and zirconium.

In all of the aforesaid embodiments, any element used in an embodiment can interchangeably be used in another embodiment unless such a replacement is not feasible or causes adverse effect. Further, the present invention can equally be applied to apparatuses and methods.

In another embodiment, the present invention provides a plasma CVD apparatus for processing a substrate, comprising: (i) a vacuum chamber having an inner wall; (ii) an upper electrode (e.g. a shower-plate) installed inside the vacuum chamber; (iii) a susceptor serving as a lower electrode provided with a heater and having a substrate-supporting area for placing the substrate thereon, said susceptor facing (e.g., conductively-coupled to) the shower-plate, enclosed by the inner wall with a gap between an outer periphery of the susceptor and the inner wall, and positioned at a processing position for processing the substrate; and (iv) a means for minimizing a floating potential charged on the substrate when a plasma is generated.

In another aspect, the present invention provides a method for processing a substrate using any one of the plasma CVD apparatus described above, comprising: (I) placing the substrate on a top surface of the susceptor; (II) generating a plasma in the chamber; and (III) confining the plasma above the substrate using the insulation plate, thereby minimizing a floating potential charged on the substrate. Further, the present invention provides a method for processing a substrate, comprising: (I) a step of placing a substrate on a susceptor installed in a chamber of a plasma CVD apparatus; (II) a step of generating a plasma in the chamber; and (III) a step for minimizing a floating potential charged on the substrate, thereby forming a thin film on the substrate.

In the present disclosure where conditions and/or structures are not specified, the skilled artisan in the art can readily provide such conditions and/or structures, in view of the present disclosure, as a matter of routine experimentation.

The present invention will be explained with reference to the drawings. However, the drawings are not intended to limit the present invention.

[Apparatus Structure]

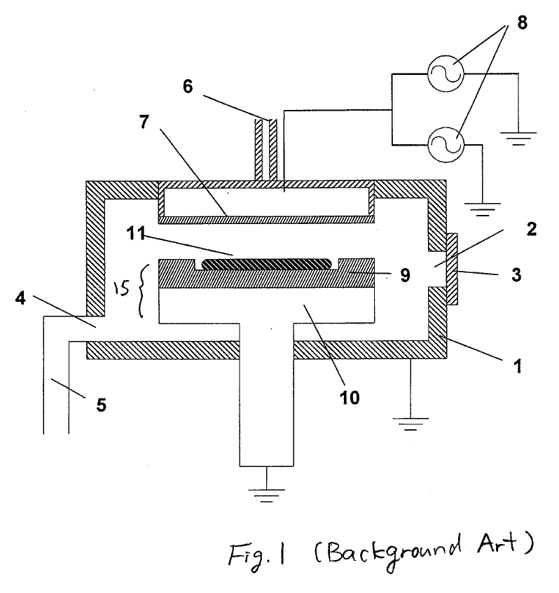

On manufacturing lines using semiconductor apparatuses, dry etching, plasma CVD and other plasma processes are widely used. The plasma CVD apparatus shown in FIG. 1 is one example of the apparatus used to implement these plasma processes. However, the present invention is not limited to apparatuses of this type, but it can also be applied to apparatuses that are structured to enlarge the plasma area to cover the gaps between the susceptor and interior walls of the reactor.

[Overall]

This plasma CVD apparatus for forming a film on a semiconductor substrate, as illustrated in FIG. 1, comprises a reactor chamber 1, a susceptor 15 (with a top plate 9 and a heating block 10) on which to place the semiconductor substrate 11, a showerhead 7 facing the susceptor and connected to a gas introduction pipe 6 used to inject reaction gas uniformly onto the semiconductor substrate, an exhaust port 4 for exhausting the interior of the reactor chamber, an opening 2 for transferring the semiconductor substrate into and out of the reactor chamber, and a high-frequency power supply 8 for applying a specified voltage.

[Opening]

The opening 2 is provided in a side face of the reactor chamber 1. The reactor chamber 1 is connected via a gate valve 3 to a transfer chamber (not shown) used to transfer a semiconductor substrate into and out of the reactor chamber.

[Exhaust Port]

The exhaust port 4 is provided inside the reactor chamber 1, where the exhaust port 4 is connected to an evacuation pump (not shown) via a piping 5. Provided between the exhaust port 4 and vacuum pump is a mechanism (not shown) for detecting and adjusting the pressure inside the reactor chamber, and this mechanism can be used to control the interior of the reactor chamber to a specified pressure.

[Upper Electrode]

The showerhead 7 is set in a position facing the aforementioned susceptor inside the reactor chamber 1.

The showerhead 7 is connected to the reaction gas introduction pipe 6 for introducing reaction gas, and the gas is ejected into the reactor chamber through several thousand pores (not shown) provided in the bottom face of the showerhead 7 for injecting the reaction gas onto a substrate. The showerhead 7 also connects electrically to the high-frequency power supply 8 to constitute one of the electrodes for implementing plasma discharge.

[Lower Electrode]

The susceptor 15 located inside the reactor chamber 1 and used to place a semiconductor substrate on top comprises the placement block 9 (top plate) that constitutes a placement surface covered with an anodized film and on which a semiconductor substrate is placed, as well as the heating block 10 (heater) that heats the semiconductor substrate using a heating element embedded inside the block.

The heating block 10 is grounded, and the susceptor constitutes one of the electrodes for implementing plasma discharge.

The placement block 9 is detachably affixed to the heating block 10 using screws, etc. However, the placement block 9 can also be connected to the heating block 10 in a non-detachable manner.

The heating block 10 is connected via a support body to a drive mechanism (not shown) for moving the susceptor 15 up and down.

Embedded inside the heating block 10 are a resistance-type heating element that is connected to an external power supply (not shown) and a temperature controller. The heating element is controlled by the temperature controller in such a way that the susceptor 15 is heated to a desired temperature (such as any temperature between 300° C. and 650° C.).

The foregoing explained the structure of the conventional apparatus shown in FIG. 1. Embodiments of the present invention are characterized as follows.

[Insulator]

In a representative example of the invention specified in the present application for patent, an insulation plate is set around the susceptor.

The insulation plate is affixed to the interior of the reactor in an embodiment, or placed on the susceptor so that it can move together with the susceptor.

The position at which the insulation plate is placed is explained. If the insulation plate is set above the surface of the top plate, it is sufficient that the bottom of the insulation plate is positioned at a height equal to or below the surface of the top plate. If the insulation plate is set below the surface of the top plate, it is sufficient that the top of the insulator is positioned at a height equal to or above the bottom face of the heating block. In other words, the insulation plate can be placed at any position as long as virtually no gaps form between the susceptor and insulation plate and the plasma generation area can be limited. Normally a ring-shaped piece having a constant thickness is used to constitute the insulation plate, but it can have a raised periphery or otherwise have multiple thicknesses.

The insulator is normally made of ceramics or quartz, but its material is not limited to these two. Specifically, it is sufficient that the insulator is made of at least one of the materials that include oxides, nitrides and fluorides of aluminum, magnesium, silicon, titanium and zirconium. Specific examples of the present invention are explained below. It should be noted, however, that the present invention is not limited to these examples.

By the way, the floating potential can be measured using the method illustrated in FIG. 14. To be specific, a voltage-measuring electrode is connected to a wafer 134 and also to an AC component filter 132 that is grounded and installed outside the reactor, and then a DC voltage is output to measure the voltage using a measuring equipment 131. As a reference, theoretically the substrate is charged with negative electricity in plasma discharge, and therefore the floating potential should always become negative. In actual film forming processes, however, sometimes the substrate is charged with positive electricity. In the present invention, therefore, reducing the floating potential means reducing the absolute value of floating potential regardless of whether the potential is negative or positive.

### EXAMPLE 1

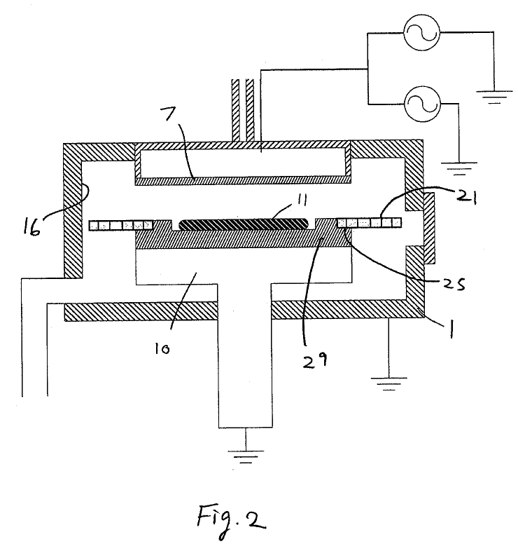

FIG. 2 shows the best mode of embodiment 1. In this example, an insulation plate 21 is placed on the susceptor 15 and moves together with the susceptor 15, as shown in FIG. 2.

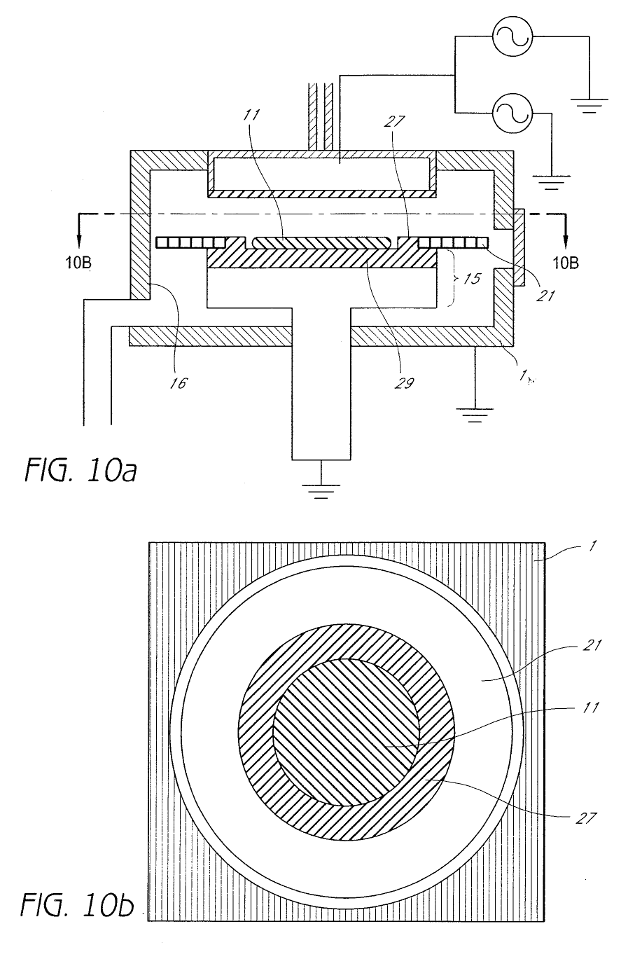

The insulation plate 21 comprises a ceramic disc whose thickness is in a range of approx. 1 mm to approx. 10 mm (or preferably in a range of 1 mm to 5 mm, or more preferably in a range of 2 mm to 4 mm), and whose inner diameter is greater than the semiconductor substrate 11 while whose outer diameter is equal to or greater than 95% of the distance from a top plate 29 to an interior wall 16. In other words, the insulation plate must not contact the semiconductor substrate 11, and its inner diameter must be smaller than the semiconductor substrate 11 so that the insulation plate will not overlap with the semiconductor substrate 11. FIG. 10(b) shows a cross-section BB of the structure shown in FIG. 10(a). The gap between the substrate 11 and a lip 27 is not shown. The insulator 21 is attached to the outer periphery of the lip 27 on the top face of the top plate 29 so that the gap between the susceptor 15 and interior wall 16 of the reactor 1 can be sealed.

A step 25 is provided around the top plate 29 for placing the insulation plate 21. The insulation plate 21 is placed on the step and moves together with the top plate 29.

Because of this insulation plate 21, areas located below the insulation plate 21 where a conductive member is exposed can be insulated from plasma.

Experiment using Variation Example 1

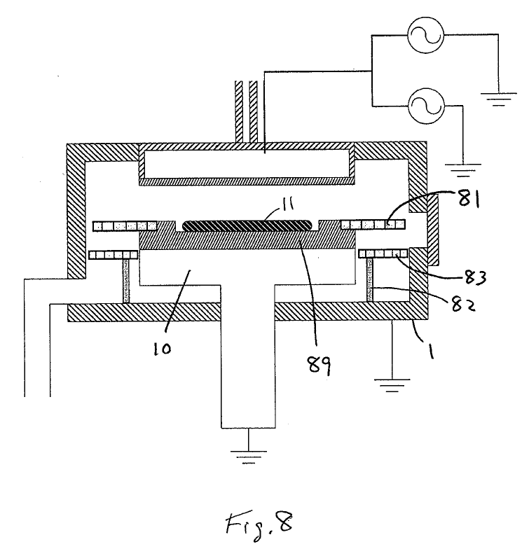

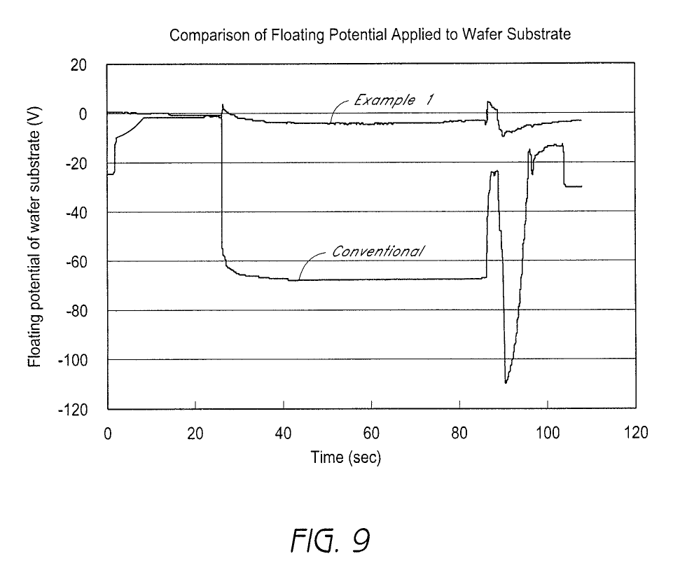

FIG. 9 shows the measured floating potentials applied to a semiconductor substrate when the conventional apparatus and the apparatus shown in Variation Example 1 were used, respectively. Eagle®-10 (ASM Japan, Tokyo) was used as the conventional apparatus, while an apparatus having an insulation plate 211 (made of ceramics and having a thickness of 5 mm, inner diameter of 246 mm and outer diameter of 370 mm) fitted on the outer side periphery of a top plate 215 of Eagle®-10 was used as the apparatus according to Variation Example 1, as shown in FIG. 12 (there was virtually no height difference between the top face of the insulation plate 211 and top face of the top plate 215). The numerals used in this figure represent the following: 202: ring duct (made of aluminum); 207: opening; 208: reactor body; 210: upper body; 211: insulation plate; 212: shower plate; 213: 214: top plate; 215: heater; 216: shield plate (made of ceramics).

The applicable conditions are specified below.

Various Conditions

| Heater | Showerhead | Wall | Electrode |
|---|---|---|---|
| temperature | temperature | temperature | gap |
| (° C.) | (° C.) | (° C.) | (mm) |
| 400 | 130 | 110 | 10 |

TEOS Film Forming Conditions

| TEOS | N2O | Pressure | HRF | LRF | Film forming time |
|---|---|---|---|---|---|
| (sccm) | (sccm) | (Torr) | (W) | (W) | (sec) |
| 86 | 800 | 3.00 | 285 | 250 | 60 |

As evident from the graph in FIG. 9, as much as around −70 V of floating potential applied to the semiconductor substrate when the conventional apparatus was used decreased to −4 V when the apparatus conforming to the present invention was used. Also, under the apparatus conforming to the present invention the fluctuation in floating potential was minimal and the floating potential remained roughly constant around zero while the substrate was processed. It is shown, therefore, that the floating potential applied to the semiconductor substrate can be reduced dramatically by using the insulation plate.

Other Variations of Example 1

In Example 1, the outer diameter of the insulator 21 was equal to or above 95% of the distance from the top plate 29 to the interior wall 16. However, the intended effects can be achieved as long as the outer diameter is at least one half the distance from the top plate 29 to the interior wall 16.

Also, the thickness of the insulator 21 may not be in a range of 1 to 10 mm as specified in Example 1, as long as the thickness is enough to shield plasma.

In Example 1, the height of the insulator 21 was roughly the same as the height of the top face of the top plate 29. However, the two can be positioned at different heights.

In Example 1, the insulation plate 21 was simply placed on a step. However, it is desirable to affix it to the top plate 29 by means of screws, etc.

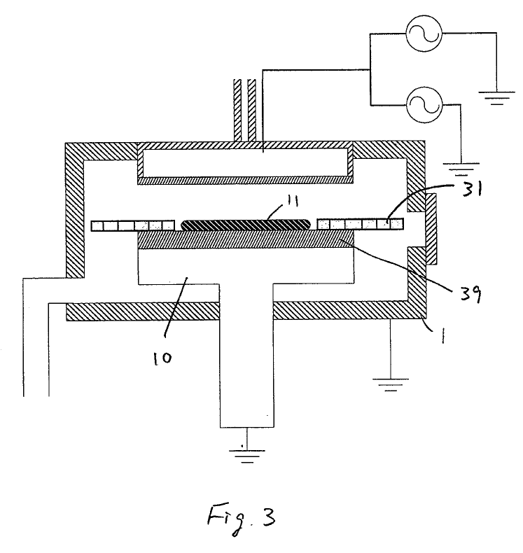

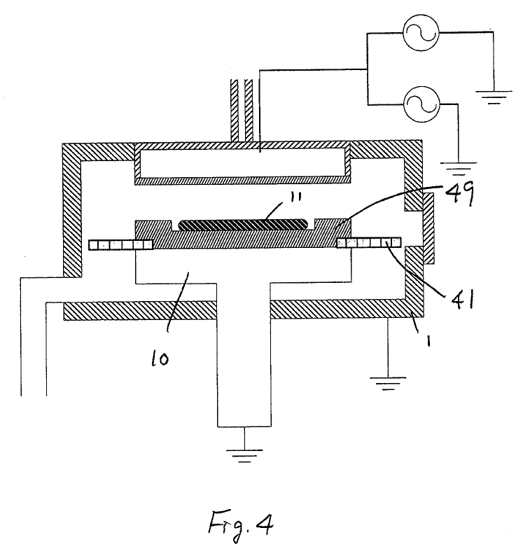

When placing the insulation plate 21 on the susceptor, it is not necessary to provide a step on the top plate 29. Instead, the insulation plate may be affixed to the susceptor in a manner movable together with the susceptor, as shown in FIGS. 3 through 5. In FIG. 3, an insulator 31 is placed on a flat top plate 39 without lip (it is desirable that the insulator be affixed by means of screws, etc.). In this figure, the insulator 31 also serves as a lip. Here, the inner diameter of the insulation plate 31 is greater than the substrate 11. In FIG. 4, an insulator 41 is placed between a top plate 49 and the heating block 10. Here, the insulator can be placed by providing a groove in the top plate 49 or heating block 10. In this case, the inner diameter of the insulator 49 is not an issue. In FIG. 5, an insulator 51 is supported by the heating block 10. The heating block 10 has a projection 52 for placing the insulator 51. In FIG. 5, the insulator 51 is positioned near the boundary between a top plate 59 and the heating block 10 so that the side faces of the heating block 10 are not exposed to plasma. Therefore, the side faces of the heating block 10 need not be coated with an anodized film. In this case, the inner diameter of the insulator 59 is set roughly the same as the outer diameter of the heating block 10 to virtually prevent gaps from forming between the heating block 10 and insulator 59.

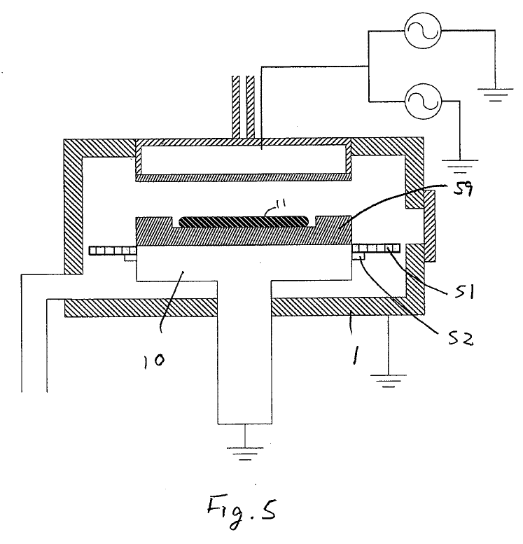

Also, the insulation plate may not be flat. As shown in FIG. 6, the insulation plate may have a step and raised periphery or otherwise have multiple thicknesses. To be specific, in FIG. 6 an insulator 61 is extending from a side face of the heating block 10 and an insulator 61 a is extending vertically from the outer periphery of the insulator 61. This way, the insulator 61a can limit the plasma area more effectively to limit the spreading of plasma to below the heating block and also to the lower sections of the interior walls of the reactor. The length of this vertical insulator 61a is in a range of approx. 5 mm to 50 mm (or preferably in a range of 20 mm±5 mm). In FIG. 6, the insulator 61 is supported on a side face of the heating block, as in FIG. 5. However, a projection 62 is provided near the bottom face of the heating block and therefore other side faces of the heating block are exposed to plasma. In this configuration, therefore, it is desirable that the side faces of the heating block be coated with an anodized film.

By affixing the insulation plate to the heating block in this manner, gaps will not form between the heating block and insulation plate. Also, by affixing the insulation plate to the heating block in a movable manner, the insulation plate can be placed in an area not possible under the method in which the insulation plate is affixed to aid in the transfer of semiconductor substrates.

### EXAMPLE 2

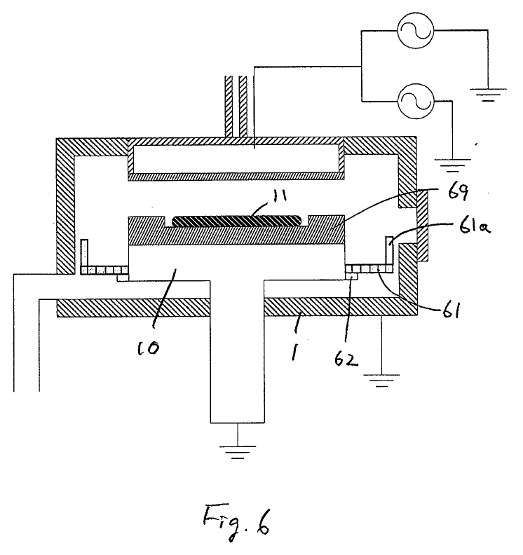

In Example 2, the insulation plate is affixed. As shown in FIG. 7, an insulator 71 is affixed on a support 72 at the bottom of the reactor 1 so that its position aligns with the height of the bottom edge of the top plate (i.e., the insulator is positioned in a manner preventing the heating block 10 from being exposed).

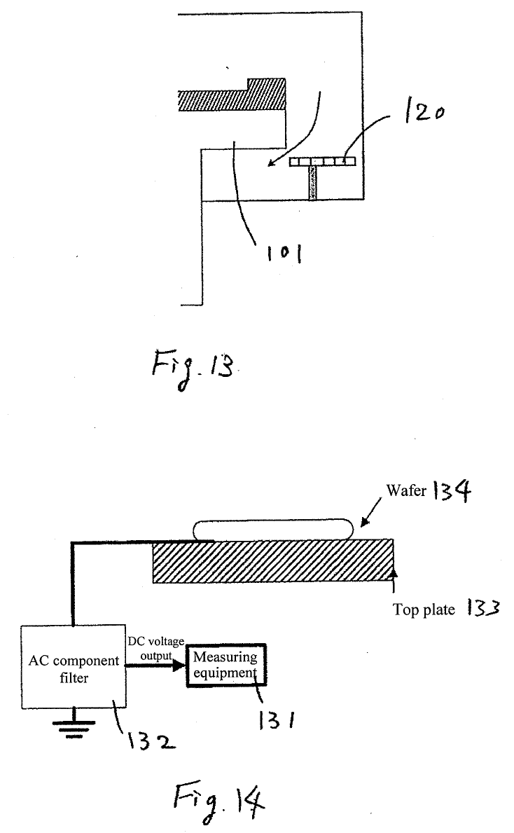

Here, the insulator 71 may preferably be set above the bottom face of the heating block 10. FIG. 13 shows an example where an insulator 120 is arranged below the bottom face of a heating block 101. According to this structure, plasma enters the space between the heating block 101 and insulator 120, which is undesirable.

Desirably the gap between the susceptor and insulator may be minimized. Even when the insulator is affixed to the bottom of the reactor, the gap from the susceptor may preferably be kept to 2 mm or less.

The inner diameter of the insulation plate 71 is roughly the same as the outer diameter of the susceptor, while the outer diameter of the insulation plate corresponds to 95% of the distance from a top plate 79 to the interior wall, in the same manner as explained in Example 1.

Variations of Example 2

In Example 2, the height of the insulation plate 71 was the same as the height of the bottom edge of the top plate. However, the heights of the two may not be the same as long as gaps do not virtually form between the susceptor and insulation plate.

If the insulation plate is set above the bottom edge of the top plate 79, it is sufficient that the bottom of the insulation plate 71 is at a height equal to or below the surface of the top plate 79. If the insulation plate is set below the surface of the top plate 79, it is sufficient that the top of the insulator 71 is at a height equal to or above the bottom face of the heating block.

The thickness, outer diameter and material of the insulation plate 71 may conform to those explained in Example 1.

By affixing the insulation plate to the reactor in this manner, the insulator temperature will not rise as much as when the insulation plate is affixed to the susceptor, which is advantageous when a material of lower heat resistance is used.

### EXAMPLE 3

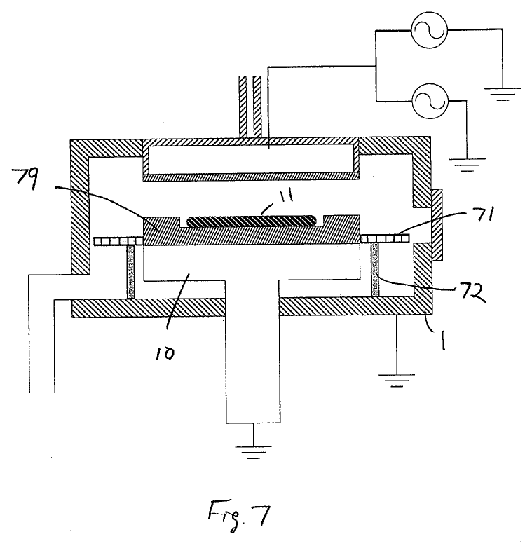

In Example 3, multiple insulation plates are used. FIG. 8 shows one example of this configuration. This configuration is characterized by setting two or more of the insulation plate shown in Example 1 and Example 2. A desired pattern of combination or number of insulation plates can be selected according to the apparatus.

In FIG. 8, one insulation plate 81 (movable insulation plate) is affixed onto the susceptor (top plate 89), while another insulation plate 83 (fixed insulation plate) is affixed onto the reactor 1. The two insulation plates are respectively set in positions where the insulation plates will not contact each other even when the susceptor moves up and down. Here, the movable insulation plate is positioned above, while the fixed insulation plate is positioned below. Accordingly, having a slight gap between the susceptor and fixed insulation plate positioned below will not present any problem because plasma can be shielded by the movable insulation plate positioned above.

When multiple insulation plates are used in this way, the positions and shapes of insulation plate can be set in a more flexible manner to achieve greater effects in situations where using one insulation plate is not sufficiently effective.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A plasma CVD apparatus for processing a substrate, comprising:
a vacuum chamber having an inner wall;
an upper electrode installed inside the vacuum chamber;
a susceptor serving as a lower electrode provided with a heater and having a substrate-supporting area for placing the substrate thereon, said susceptor facing the upper electrode, enclosed by the inner wall with a gap between an outer periphery of the susceptor and the inner wall, and positioned at a processing position for processing the substrate; and
at least one plasma blocking insulation plate disposed in the gap in the vicinity of or in contact with the susceptor and surrounding all around the susceptor when at the processing position, the insulation plate having an upper surface, a lower surface, and an outer periphery, wherein the lower surface of the insulation plate is not higher than a top surface of the susceptor in an axial direction of the susceptor, the upper surface of the insulation plate is not lower than a lower end of the susceptor, the outer periphery of the insulation plate is located closer to the inner wall of the chamber than to the periphery of the susceptor when at the processing position.

2. The plasma CVD apparatus according to claim 1, wherein the insulation plate has an inner periphery which has a diameter greater than a diameter of the substrate-supporting area to be placed on the susceptor.

3. The plasma CVD apparatus according to claim 1, wherein a distance A from the outer periphery of the susceptor to the outer periphery of the insulation plate and a distance B from the outer periphery of the insulation plate to the inner wall of the chamber satisfy the following equation: A/(A+B)=70-99%.

4. The plasma CVD apparatus according to claim 1, wherein the insulation plate is ring-shaped and attached to the susceptor.

5. The plasma CVD apparatus according to claim 1, wherein the insulation plate is ring-shaped and fixed to the chamber.

6. The plasma CVD apparatus according to claim 4, wherein the susceptor has an annular lip portion on its top surface outside the substrate-supporting area, and the insulation plate is disposed on the top surface outside the lip portion.

7. The plasma CVD apparatus according to claim 4, wherein the top plate has no annular lip portion on a top surface outside the substrate-supporting area, and the insulation plate is disposed on the top surface outside the substrate-supporting area.

8. The plasma CVD apparatus according to claim 1, wherein the susceptor is comprised of a top plate and a heating block on which the top plate is placed, wherein the insulation plate is ring-shaped and attached to the top plate.

9. The plasma CVD apparatus according to claim 1, wherein the susceptor is comprised of a top plate and a heating block on which the top plate is placed, wherein the insulation plate is ring-shaped and interposed between the top plate and the heating block.

10. The plasma CVD apparatus according to claim 1, wherein the susceptor is comprised of a top plate and a heating block on which the top plate is placed, wherein the insulation plate is ring-shaped and attached to a side of the heating block.

11. The plasma CVD apparatus according to claim 1, wherein the susceptor is comprised of a top plate and a heating block on which the top plate is placed, wherein the insulation plate has a ring portion and an annular upright peripheral portion, said ring portion being attached to a side of the heating block.

12. The plasma CVD apparatus according to claim 1, wherein the susceptor is comprised of a top plate and a heating block on which the top plate is placed, wherein the insulation plate is ring-shaped, fixed to a bottom of the chamber with a support, and disposed at or near a boundary between the top plate and the heating block when at the processing position.

13. The plasma CVD apparatus according to claim 1, wherein the at least one insulation plate is composed of two insulation plates installed in different positions.

14. The plasma CVD apparatus according to claim 13, wherein one of the insulation plates is attached to a top surface of the susceptor, and the other insulation plate is fixed to a bottom of the chamber with a support.

15. The plasma CVD apparatus according to claim 1, wherein the insulation plate is placed to minimize a floating potential charged on the substrate when a plasma is generated.

16. The plasma CVD apparatus according to claim 1, wherein the insulation plate is made of a material selected from the group consisting of oxides, nitrides, and fluorides of aluminum, magnesium, silicon, titanium, and zirconium.

17. A plasma CVD apparatus for processing a substrate, comprising:
a vacuum chamber having an inner wall;
an upper electrode installed inside the vacuum chamber;
a susceptor serving as a lower electrode provided with a heater and having a substrate-supporting area for placing the substrate thereon, said susceptor facing the upper electrode, enclosed by the inner wall with a gap between an outer periphery of the susceptor and the inner wall, and positioned at a processing position for processing the substrate; and
a means for minimizing a floating potential charged on the substrate when a plasma is generated.

18. A method for processing a substrate using a plasma CVD apparatus comprising:
a vacuum chamber having an inner wall;
an upper electrode installed inside the vacuum chamber;
a susceptor serving as a lower electrode provided with a heater and having a substrate-supporting area for placing the substrate thereon, said susceptor facing the upper electrode, enclosed by the inner wall with a gap between an outer periphery of the susceptor and the inner wall, and positioned at a processing position for processing the substrate; and
at least on insulation plate disposed in the gap in the vicinity of or in contact with the susceptor and surrounding all around the susceptor when at the processing position, the insulation plate having an upper surface, a lower surface, and an outer periphery, wherein the lower surface of the insulation plate is not higher than a top surface of the susceptor in an axial direction of the susceptor, the upper surface of the insulation plate is not lower than a lower end of the susceptor, the outer periphery of the insulation plate is located closer to the inner wall of the chamber than to the periphery of the susceptor when at the processing position,
said method comprising:
placing the substrate on a top surface of the susceptor;
generating a plasma in the chamber; and
confining the plasma above the substrate using the insulation plate, thereby minimizing a floating potential charged on the substrate.

19. A method for processing a substrate, comprising:
a step of placing a substrate on a susceptor installed in a chamber of a plasma CVD apparatus;
a step of generating a plasma in the chamber; and
a step for minimizing a floating potential charged on the substrate, thereby processing the substrate.
